(19) United States
(12) Patent Application Publication
(10) Pub. No.: US 2025/0096192 A1
(43) Pub. Date: Mar. 20, 2025

(54) PACKAGE STRUCTURE AND FABRICATING METHOD THEREOF

(71) Applicant: KORE SEMICONDUCTOR CO., LTD., Qingdao (CN)

(72) Inventors: Ghang-Chun LAI, Qingdao (CN); Meng-Huang SIE, Qingdao (CN); Cheng-Hao HEH, Qingdao (CN); Ming-Chin HSU, Qingdao (CN)

(21) Appl. No.: 18/741,020

(22) Filed: Jun. 12, 2024

(30) Foreign Application Priority Data
Sep. 14, 2023 (CN) 202311183893.3

(51) Int. Cl. H01L 23/00; H01L 25/065

(52) U.S. Cl. CPC H01L 24/81; H01L 24/11; H01L 24/13; H01L 25/0657; H01L 2224/11015; H01L 2224/13007; H01L 2224/81139; H01L 2224/81935

(57) ABSTRACT

A package structure is provided, in which a second electronic element having a plurality of conductive bumps is stacked on a first electronic element arranged with a positioning layer. The plurality of conductive bumps are inserted into a plurality of positioning holes of the positioning layer, and the second electronic element is bonded onto the positioning layer and electrically connected to the first electronic element via the plurality of conductive bumps, such that the hybrid bonding technology is replaced via the arrangement of the positioning holes and the conductive bumps, thereby reducing packaging costs.

### BACKGROUND

### 1. Technical Field

The present disclosure relates to a semiconductor packaging process, and more particularly, to a package structure having a positioning mechanism and a fabricating method thereof.

### 2. Description of Related Art

In response to the current development of electronic products that are becoming thinner, smaller, and more efficient, three-dimensional integrated circuits (3D IC) are a three-dimensional stacking and integration model of chips, which can not only shorten the length of metal wires and connection resistance, but also reduce the area of the chip. The three-dimensional stacking and integration model of chips has the characteristics of small size, high integration, low power consumption and low cost, and is considered to be the next generation of new semiconductor technology.

FIG. 1 is a schematic cross-sectional view of a conventional package structure 1. In the package structure 1, two semiconductor chips 10, 11 are joined together, and each semiconductor chip 10, 11 includes a chip body 100, 110, a passivation layer 101, 111 formed on the chip body 100, 110, and a plurality of metal pads 102, 112 formed on the chip body 100, 110, so that the metal pads 102, 112 are exposed from the passivation layer 101, 111, and the two semiconductor chips 10, 11 are in contact with each other via their metal pads 102, 112 and are fixedly bonded to each other. The two semiconductor chips 10, 11 are bonded using a hybrid bonding method, wherein the metal pads 102, 112 are made of copper, the passivation layers 101, 111 are made of silicon dioxide (SiO₂), then the passivation layers 101, 111 of the two semiconductor chips 10, 11 are brought together (a contact surface S as shown in FIG. 1) and heated (approximately 100° C.) to fuse the two passivation layers 101, 111, so that the metal pads 102, 112 of the two semiconductor chips 10, 11 are aligned, and then the metal pads 102, 112 are heated (about 300° C.), such that the metal pads 102, 112 are expanded to contact each other for electrical connection.

However, in the conventional package structure 1, during the hybrid bonding operation, the passivation layers 101, 111 are inorganic insulating layers, and their surfaces need to be very smooth and clean so that the passivation layers 101, 111 of the two semiconductor chips 10, 11 can be completely in contact, such that the metal pads 102, 112 of the two semiconductor chips 10, 11 can be accurately butted and electrically connected. Therefore, it takes a lot of time to detect the leveling and cleaning operations on the surface of the passivation layer 101, 111, and it is also necessary to use extremely high-precision special leveling equipment and special cleaning equipment for the leveling and cleaning operations. Accordingly, the required process equipment is extremely expensive, and even special heating equipment (such as having the function of heating over 300° C.) is required. As a result, the overall packaging cost of the package structure 1 using the hybrid bonding method is extremely expensive, making it difficult to be widely used in electronic products.

Therefore, how to overcome the above-mentioned problems of the prior art has become an urgent issue to be solved.

### SUMMARY

In view of the various deficiencies of the prior art, the present disclosure provides a package structure, which comprises: a first electronic element having a plurality of first electrode pads; a positioning layer formed on the first electronic element and having a plurality of positioning holes exposing the plurality of first electrode pads; and a second electronic element disposed on the positioning layer and having a plurality of second electrode pads, wherein the plurality of second electrode pads are provided with a plurality of conductive bumps accommodated in the plurality of positioning holes, so that each of the plurality of conductive bumps is in contact with each of the plurality of first electrode pads, such that the second electronic element is electrically connected to the first electronic element via the plurality of conductive bumps.

The present disclosure further provides a method of fabricating a package structure, the method comprises: providing a first electronic element having a plurality of first electrode pads and a second electronic element having a plurality of second electrode pads; forming a positioning layer on the first electronic element, and forming a plurality of conductive bumps on the plurality of second electrode pads of the second electronic element, wherein the positioning layer has a plurality of positioning holes exposing the plurality of first electrode pads; inserting the plurality of conductive bumps into the plurality of positioning holes, so that the second electronic element is bonded onto the positioning layer, wherein the plurality of conductive bumps are free from being in contact with the plurality of first electrode pads in the plurality of positioning holes; and heating the plurality of conductive bumps, so that each of the plurality of conductive bumps is in contact with each of the plurality of first electrode pads, wherein the second electronic element is electrically connected to the first electronic element via the plurality of conductive bumps.

In the aforementioned package structure and method, there is a gap between each of the plurality of conductive bumps and a wall surface of each of the plurality of positioning holes after heating the plurality of conductive bumps.

In the aforementioned package structure and method, each of the plurality of conductive bumps includes a conductive pillar used to bond to each of the plurality of second electrode pads and a conductive bonding material formed on the conductive pillar. For example, the conductive bonding material is a solder material.

In the aforementioned package structure and method, a material for forming the positioning layer is an organic insulating material.

As can be seen from the above, in the package structure and the fabricating

method thereof of the present disclosure, the second electronic element is fixedly stacked above the first electronic element via the arrangement of the positioning holes and the conductive bumps, and the first electronic element and the second electronic element are electrically connected via the plurality of conductive bumps, thereby replacing the conventional hybrid bonding technology. Therefore, compared with the prior art, the present disclosure only needs to use conventional equipment instead of special equipment, thus significantly reducing packaging costs.

### BRIEF DESCRIPTION OF THE DRAWINGS

FIG. 1 is a schematic cross-sectional view of a conventional package structure.

FIG. 2A to FIG. 2E are schematic cross-sectional views illustrating a fabricating method of a package structure according to the present disclosure.

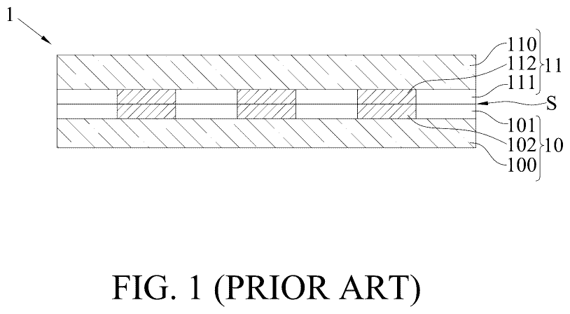

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

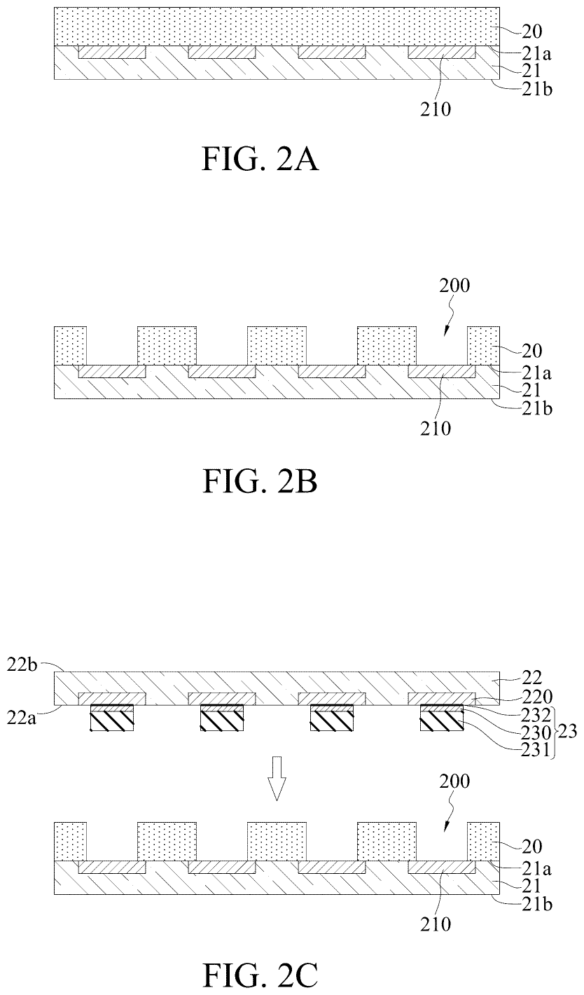

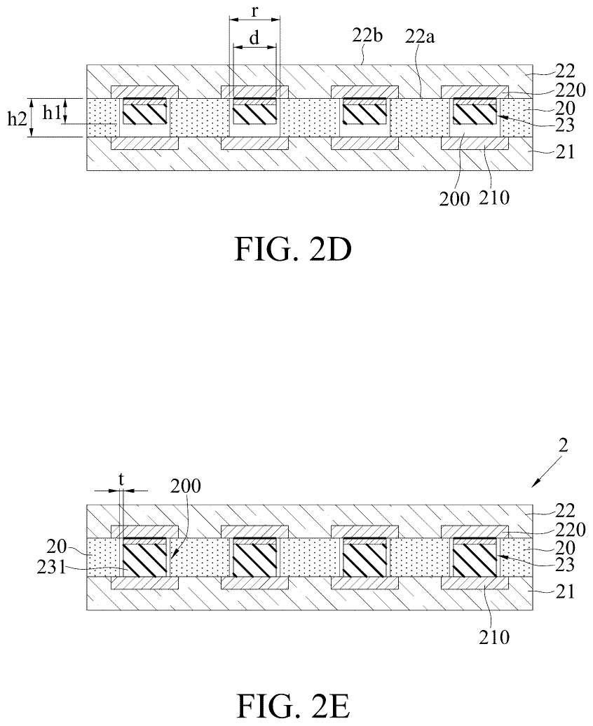

FIG. 2A to FIG. 2E are schematic cross-sectional views illustrating a fabricating method of a package structure 2 according to the present disclosure.

As shown in FIG. 2A, a first electronic element 21 having a plurality of first electrode pads 210 is provided, and a positioning layer 20 covering the first electrode pads 210 is formed on the first electronic element 21.

The first electronic element 21 is an active element, a passive element, or a combination thereof and the like, wherein the active element is, for example, a semiconductor chip, and the passive element is, for example, a resistor, a capacitor, or an inductor. In one embodiment, the first electronic element 21 is a semiconductor chip or of a wafer specification and has a first active surface 21a and a first inactive surface 21b opposing the first active surface 21a, and the plurality of first electrode pads 210 are formed at the first active surface 21a.

The positioning layer 20 can be formed on the first active surface 21a of the first electronic element 21 by lamination or molding.

In one embodiment, the positioning layer 20 is an insulating layer and is made of organic insulating material like dielectric material such as polybenzoxazole (PBO), polyimide (PI), prepreg (PP), Ajinomoto build-up film (ABF) and the like, or solder-resist material such as solder mask (e.g., green solder mask) and graphite. Preferably, the thermal curing temperature of the positioning layer 20 is less than or equal to 200° C. It should be understood that there are many types of organic insulating materials, which can be selected according to needs and are not limited to the above.

As shown in FIG. 2B, a patterning process is performed to form a plurality of positioning holes 200 on the positioning layer 20, so that each of the first electrode pads 210 is exposed correspondingly from each of the positioning holes 200.

In one embodiment, the patterning process uses such as laser drilling, machine drilling, etching, exposure and development, or other methods to form the positioning holes 200.

As shown in FIG. 2C, a second electronic element 22 having a plurality of second electrode pads 220 is provided, and a conductive bump 23 is formed on each of the second electrode pads 220.

The second electronic element 22 is an active element, a passive element, or a combination thereof and the like, wherein the active element is, for example, a semiconductor chip, and the passive element is, for example, a resistor, a capacitor, or an inductor. In one embodiment, the second electronic element 22 is a semiconductor chip or of a wafer specification and has a second active surface 22a and a second inactive surface 22b opposing the second active surface 22a, and the plurality of second electrode pads 220 are formed at the second active surface 22a.

The conductive bump 23 includes a conductive pillar 230 for bonding the second electrode pad 220 and a conductive bonding material 231 formed on the conductive pillar 230.

In one embodiment, the conductive pillar 230 is a metal pillar such as a copper pillar, and the conductive bonding material 231 is a solder material, and the reflow temperature of the conductive bonding material 231 is about 200° C. to 270° C. Preferably, an under bump metallization (UBM) layer 232 can be formed between the conductive pillar 230 and the second electrode pad 220, so as to facilitate the second electrode pad 220 to be bonded to the conductive pillar 230 via the under bump metallization layer 232. There are various aspects of the composition of the conductive pillar 230, such as a titanium/copper/nickel composite metal pillar, and the present disclosure is not limited to as such.

Furthermore, the conductive pillar 230 is formed by a patterning process, such as electroplating, etching, deposition, sputtering, or other suitable methods, and the present disclosure is not limited to as such.

As shown in FIG. 2D, the conductive bumps 23 on the second electrode pads 220 of the second electronic element 22 are inserted into the positioning holes 200 of the positioning layer 20 on the first electronic element 21, so that the second active surface 22a of the second electronic element 22 is brought into contact with the positioning layer 20, such that the second electronic element 22 is stacked on top of the first electronic element 21, wherein an overall height h1 of the conductive bump 23 is less than a depth h2 of the positioning hole 200, so the conductive bump 23 has not yet contacted the first electrode pad 210 in the positioning hole 200.

In an embodiment, a width d of the conductive bump 23 is less than a width r of the positioning hole 200, so as to facilitate the insertion of the conductive bump 23 into the positioning hole 200.

Furthermore, the positioning layer 20 can be thermally cured via the first heating process, so that the second electronic element 22 is fixedly stacked above the first electronic element 21, wherein the operating temperature of the first heating process is less than or equal to 200° C.

As shown in FIG. 2E, a second heating process is performed to heat the conductive bumps 23 so that the conductive bonding materials 231 expand and are in contact with the first electrode pads 210, such that the first electronic element 21 is electrically connected to the second electronic element 22 via the conductive bumps 23, wherein each of the positioning holes 200 is not filled up by each of the conductive bumps 23, so that there is a gap t between each of the conductive bumps 23 and the wall surface of each of the positioning holes 200.

In one embodiment, the second heating process is to reflow the conductive bonding materials 231 of the conductive bumps 23, wherein the operating temperature of the reflow operation is between 220° C. and 270° C., such as 230° C.

Therefore, the fabricating method of the present disclosure mainly uses organic insulating material to form the positioning layer 20, and configures the positioning holes 200 for the conductive bumps 23 to cooperate, so as to facilitate the conductive bumps 23 to contact the first electrode pads 210 of the first electronic element 21. Therefore, compared with the conventional hybrid bonding technology, the fabricating method of the present disclosure does not need to overly take the surface flatness and cleanliness of the positioning layer 20 into account. Accordingly, conventional leveling equipment and conventional cleaning equipment suitable for the organic insulating material can be selected to help reduce production costs. It should be noted that in the fabricating method of the present disclosure, the surface flatness and cleanliness of the positioning layer 20 still need to meet the requirements, but there is no need to have the same specifications as the surface flatness and cleanliness of the conventional passivation layer. Therefore, the fabricating method of the present disclosure does not require the use of special leveling equipment and special cleaning equipment.

Furthermore, the fabricating method of the present disclosure uses the conductive bumps 23 to bond the first electronic element 21 and the second electronic element 22, so that the conductive bumps 23 containing solder material and conventional reflow equipment can be selected. Therefore, compared with the prior art, the fabricating method of the present disclosure does not require the use of special heating equipment, thereby significantly reducing the production cost.

The present disclosure also provides a package structure 2, which comprises: a first electronic element 21 having a plurality of first electrode pads 210, a positioning layer 20 formed on the first electronic element 21, and a second electronic element 22 having a plurality of second electrode pads 220.

The positioning layer 20 has a plurality of positioning holes 200 exposing the first electrode pads 210.

The second electronic element 22 is disposed on the positioning layer 20, wherein the plurality of second electrode pads 220 are provided with a plurality of conductive bumps 23 accommodated in the positioning holes 200, so that each of the conductive bumps 23 is in contact with each of the first electrode pads 210, such that the second electronic element 22 is electrically connected to the first electronic element 21 via the plurality of conductive bumps 23.

In one embodiment, there is a gap t between the conductive bump 23 and the wall surface of the positioning hole 200.

In one embodiment, the conductive bump 23 includes a conductive pillar 230 used to bond to the second electrode pad 220 and a conductive bonding material 231 formed on the conductive pillar 230. For example, the conductive bonding material 231 is a solder material.

In one embodiment, the material for forming the positioning layer 20 is an organic insulating material.

In summary, the package structure and the fabricating method thereof of the present disclosure can be used to reduce fabricating costs via the design of the positioning layer and conductive bumps. Therefore, the present disclosure can be widely used in electronic products.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A package structure, comprising:
a first electronic element having a plurality of first electrode pads;
a positioning layer formed on the first electronic element and having a plurality of positioning holes exposing the plurality of first electrode pads; and
a second electronic element disposed on the positioning layer and having a plurality of second electrode pads, wherein the plurality of second electrode pads are provided with a plurality of conductive bumps accommodated in the plurality of positioning holes, so that each of the plurality of conductive bumps is in contact with each of the plurality of first electrode pads, such that the second electronic element is electrically connected to the first electronic element via the plurality of conductive bumps.

2. The package structure of claim 1, wherein there is a gap between each of the plurality of conductive bumps and a wall surface of each of the plurality of positioning holes.

3. The package structure of claim 1, wherein each of the plurality of conductive bumps includes a conductive pillar used to bond to each of the plurality of second electrode pads and a conductive bonding material formed on the conductive pillar.

4. The package structure of claim 3, wherein the conductive bonding material is a solder material.

5. The package structure of claim 1, wherein a material for forming the positioning layer is an organic insulating material.

6. A method of fabricating a package structure, comprising:
providing a first electronic element having a plurality of first electrode pads and a second electronic element having a plurality of second electrode pads;
forming a positioning layer on the first electronic element, and forming a plurality of conductive bumps on the plurality of second electrode pads of the second electronic element, wherein the positioning layer has a plurality of positioning holes exposing the plurality of first electrode pads;
inserting the plurality of conductive bumps into the plurality of positioning holes, so that the second electronic element is bonded onto the positioning layer, wherein the plurality of conductive bumps are free from being in contact with the plurality of first electrode pads in the plurality of positioning holes; and
heating the plurality of conductive bumps, so that each of the plurality of conductive bumps is in contact with each of the plurality of first electrode pads, wherein the second electronic element is electrically connected to the first electronic element via the plurality of conductive bumps.

7. The method of claim 6, wherein there is a gap between each of the plurality of conductive bumps and a wall surface of each of the plurality of positioning holes after heating the plurality of conductive bumps.

8. The method of claim 6, wherein each of the plurality of conductive bumps includes a conductive pillar used to bond to each of the plurality of second electrode pads and a conductive bonding material formed on the conductive pillar.

9. The method of claim 8, wherein the conductive bonding material is a solder material.

10. The method of claim 6, wherein a material for forming the positioning layer is an organic insulating material.
